(19) United States
(12) Patent Application Publication
(10) Pub. No.: US 2008/0261397 A1
(43) Pub. Date: Oct. 23, 2008

(54) Method for Manufacturing Semiconductor Device

(75) Inventors: Teyuan Yin, Shanghai (CN); Chipo Liao, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 12/060,840

(22) Filed: Apr. 1, 2008

(30) Foreign Application Priority Data
Apr. 20, 2007 (CN) 200710039810.8

(51) Int. Cl. H01L 21/4763; H01L 21/31; H01L 21/44; H01L 21/469

(52) U.S. Cl. 438/672; 438/759; 257/E21.249; 257/E21.495

(57) ABSTRACT

There is provided a method for manufacturing a semiconductor device, which includes the steps of: providing a semiconductor substrate including a gate, a source and a drain, wherein the gate includes a gate dielectric layer disposed on the semiconductor substrate; forming an etching barrier layer on the semiconductor substrate; and subjecting the resulted structure to hydrogen annealing. According to the present invention, the interface energy level between a gate dielectric layer and a semiconductor substrate is lowered and the reliability of the semiconductor device is improved.

### FIELD OF THE INVENTION

The present invention relates, in general, to a method for manufacturing a semiconductor device, and more particularly, to a method for manufacturing a semiconductor device by using hydrogen annealing.

### DESCRIPTION OF THE RELATED ART

Generally, hydrogen annealing is used to improve the Electrical connection Characteristic between metal wirings and between a metal wiring and a silicon substrate, to improve the performance and reliability of a semiconductor device, and to improve the product yield. In the manufacture of semiconductor device, hydrogen annealing is a very important treatment. For example, in a Dynamic Random-Access Memory (DRAM), there is a dangling bond between silicon oxide in an interlayer insulation layer or a gate dielectric layer of a device and silicon adjacent to a semiconductor substrate interface. Thus there exists an interface energy level between the interlayer insulation layer or gate dielectric layer and the semiconductor substrate. And a leakage current can flow from a diffusion layer to the semiconductor substrate through this interface energy level, which deteriorates the performance of the DRAM device. In hydrogen annealing, the interface is supplied with hydrogen, and the dangling bond is ended by the supplied hydrogen. As a result, the interface energy level can be lowered.

An existing method of hydrogen annealing during the manufacture of semiconductor device is shown in FIGS. 1 to 4. Referring to FIG. 1, a gate dielectric layer 103 made of silicon oxide is formed over a semiconductor substrate 100 by using thermal oxidation method; a polysilicon layer 104 is formed on the gate dielectric layer 103; then, an antireflection layer 105 is formed on the polysilicon layer 104; a first photoresist layer (not shown) is formed on the antireflection layer 105, which defines a subsequent gate pattern by exposure and development; the antireflection layer 105, the polysilicon layer 104 and the gate dielectric layer 103 are etched sequentially along the gate pattern by using the first photoresist layer as a mask until the semiconductor substrate 100 is exposed, and then a gate 106 is formed.

As shown in FIG. 2, using the gate 106 as a mask, ions are planted into the semiconductor substrate 100 at each side of the gate 106 to form a slightly doped drain 108; then spacers 114 are formed on both sides of the gate 106, which together with the gate 106 form a gate structure; using the gate structure as a mask, ions are planted into the semiconductor substrate 100 to form a source/drain 118.

As shown in FIG. 3, an etching barrier layer 120 is formed on the gate 106, spacers 114 and the source/drain 118 by chemical vapor deposition; an interlayer insulation layer 122 is deposited on the etching barrier layer 120 by chemical vapor deposition for isolation between devices; a photoresist layer (not shown) is formed on the interlayer insulation layer 122, a pattern for defining a subsequent contact hole is formed by exposure and development; using the photoresist layer as a mask, the interlayer insulation layer 122 and the etching barrier layer 120 on the gate 106 are etched along the pattern of the contact hole until the antireflection layer 105 is exposed, or the interlayer insulation layer 122 and the etching barrier layer 120 on the source/drain 118 are etched until the semiconductor substrate 100 is exposed, and then a contact hole 121 is formed.

As shown in FIG. 4, the photoresist layer is removed; a diffusion barrier layer 123 is deposited on the interlayer insulation layer 122 and on the inner surface of the contact hole by high density plasma chemical vapor deposition to prevent the subsequently deposited metal from diffusing into the interlayer insulation layer 122; a metal tungsten layer is formed on the diffusion barrier layer 123 by chemical vapor deposition, and the contact hole is completely filled with the metal tungsten layer; the diffusion barrier layer 123 and the metal tungsten layer are polished by Chemical Mechanical Polish (CMP) until the interlayer insulation layer 122 is exposed, and then a tungsten plug 124 is formed.

Then, the semiconductor substrate 100 is put into a heating oven. In the meantime, hydrogen is supplied into the heating oven to carry out annealing. As a result, the dangling bond 125 between silicon oxide in the gate dielectric layer 103 and silicon adjacent to the interface of semiconductor substrate 100 is ended and the interface energy level is lowered, and the leakage current flowing into the semiconductor substrate is avoided.

However, in recent years, with the developing tendency of semiconductor device to miniaturization, high density, multilayer and the use of new multi-layer structures, electrode materials, wiring materials and insulation materials, it becomes difficult to allow hydrogen to diffuse adequately into the desired interface through hydrogen annealing. Therefore, it is necessary to prolong the annealing time or increase the annealing temperature. However, prolonging the annealing time will cause a problem of reducing the throughput. And increasing the annealing temperature will make the metal wiring material have peaks and hillocks, which can cause a problem of decreasing the reliability. In order to resolve the above-mentioned problem, Chinese patent application No. 99125424.4 proposed performing hydrogen annealing to the semiconductor substrate with semiconductor device at different temperatures to allow the hydrogen adequately to diffuse into the desired interface.

The operations to vary temperatures make the above-mentioned process complex. Moreover, since the hydrogen has to pass through the interlayer insulation layer and the etching barrier layer before diffusing into the semiconductor substrate, the diffusion path is longer. And it is still not achieved to completely diffuse hydrogen into the semiconductor substrate. Thus, there is still an interface energy level between the gate dielectric layer and the semiconductor substrate, which causes the leakage current to flow into the semiconductor substrate and lower the reliability of the semiconductor device.

### SUMMARY OF THE INVENTION

The present invention provides a method for manufacturing a semiconductor device, according to which the interface energy level between a gate dielectric layer and a semiconductor substrate is lowered, a leakage current flowing into the semiconductor substrate is avoided and the process is simplified.

In an aspect according to the present invention, there is provided a method for manufacturing a semiconductor device, which comprises the following steps: providing a semiconductor substrate comprising a gate, a source and a drain, wherein the gate comprises a gate dielectric layer disposed on the semiconductor substrate; forming an etching barrier layer on the semiconductor substrate; and subjecting the resulted structure to hydrogen annealing.

The hydrogen annealing is carried out at a temperature in a range of 400° C. to 500° C.

The hydrogen annealing is carried out during a period in a range of 20 minutes to 30 minutes.

The etching barrier layer is made of silicon nitroxide.

The etching barrier layer has a thickness in a range of 300 angstroms to 500 angstroms.

In another aspect according to the present invention, there is provided a method for manufacturing a semiconductor device, which comprises the steps of: providing a semiconductor substrate comprising a gate, a source and a drain, wherein the gate comprises a gate dielectric layer disposed on the semiconductor substrate; forming an etching barrier layer on the semiconductor substrate; subjecting the resulted structure to hydrogen annealing; forming an interlayer insulation layer on the etching barrier layer, wherein the interlayer insulation layer overlays the gate; and forming a metal plug in the interlayer insulation layer.

The hydrogen annealing is carried out at a temperature in a range of 400° C. to 500° C.

The hydrogen annealing is carried out during a period in a range of 20 minutes to 30 minutes.

According to the present invention, since hydrogen annealing is carried out immediately after an etching barrier layer is formed; it is possible to diffuse the hydrogen into the semiconductor substrate only through the etching barrier layer. Thus, it is possible to diffuse the hydrogen completely into the semiconductor substrate and allow the dangling bond between silicon oxide in the gate dielectric layer and silicon adjacent to the interface of the semiconductor substrate to be ended. As a result, the interface energy level between the gate dielectric layer and the semiconductor substrate is lowered, which prevents the subsequent leakage current from flowing into the semiconductor substrate and thus improves the reliability of semiconductor device. Further, it is unnecessary to carry out the annealing at different temperatures according to the present invention, which simplifies the treatment.

### BRIEF DESCRIPTION OF THE DRAWINGS

FIGS. 1 to 4 are cross-sectional views illustrating a method for manufacturing a semiconductor device according to a related art;

FIG. 5 is a flow diagram illustrating a method for manufacturing a semiconductor device according to a first embodiment of the present invention;

FIG. 6 is a flow diagram illustrating a method for manufacturing a semiconductor device according to a second embodiment of the present invention;

FIGS. 7 to 12 are cross-sectional views illustrating a method for manufacturing a semiconductor device according to the present invention.

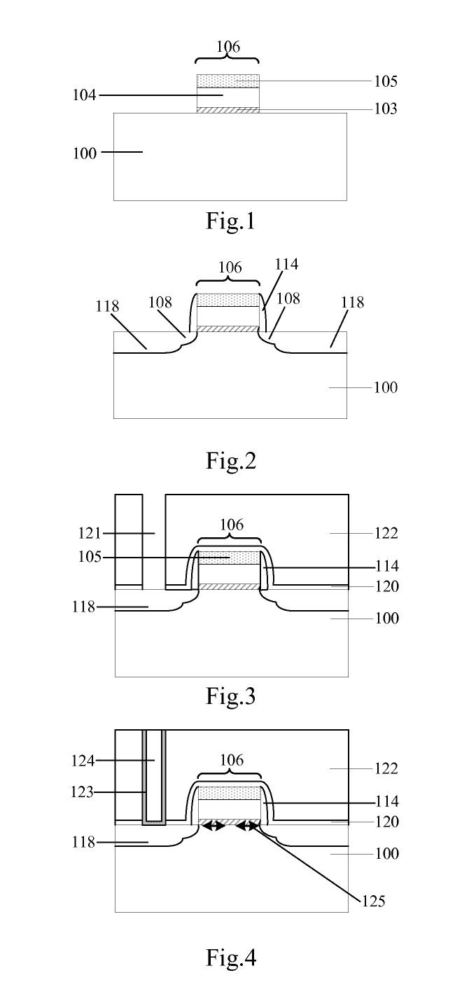

### SPECIFIC EMBODIMENTS OF THE INVENTION

As mentioned above, according to the present invention, since hydrogen annealing is carried out immediately after an etching barrier layer is formed; it is possible to diffuse the hydrogen into the semiconductor substrate only through the etching barrier layer. Thus, it is possible to diffuse the hydrogen completely into the semiconductor substrate and allow the dangling bond between silicon oxide in the gate dielectric layer and silicon adjacent to the interface of the semiconductor substrate to be ended. As a result, the interface energy level between the gate dielectric layer and the semiconductor substrate is lowered, which prevents the subsequent leakage current from flowing into the semiconductor substrate and thus improves the reliability of semiconductor device. Further, it is unnecessary to carry out the annealing at different temperatures according to the present invention, which simplifies the treatment.

The above objects, features and advantages of the present invention will become better understood with respect to the following description of the preferred embodiments given in conjunction with the accompanying drawings.

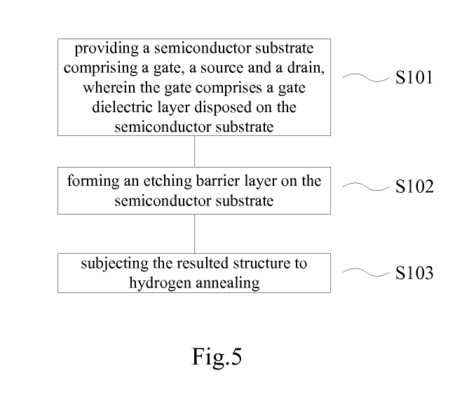

FIG. 5 is a flow diagram illustrating a method for manufacturing a semiconductor device according to a first embodiment of the present invention. As shown in FIG. 5, a semiconductor substrate comprising a gate, a source and a drain is provided, wherein the gate comprises a gate dielectric layer disposed on the semiconductor substrate (step S101); next, an etching barrier layer is formed on the semiconductor substrate (step S102); then the resulted structure is subjected to hydrogen annealing (step S103).

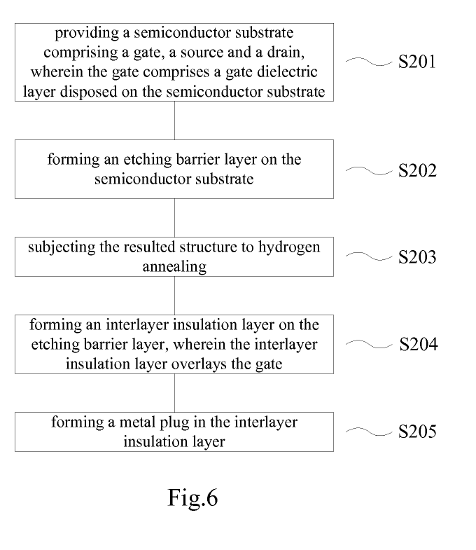

FIG. 6 is a flow diagram illustrating a method for manufacturing a semiconductor device according to a second embodiment of the present invention. As shown in FIG. 6, a semiconductor substrate comprising a gate, a source and a drain is provided, wherein the gate comprises a gate dielectric layer disposed on the semiconductor substrate (step S201); an etching barrier layer is formed on the semiconductor substrate (step S202); then the resulted structure is subjected to hydrogen annealing (step S203); an interlayer insulation layer is formed on the etching barrier layer, wherein the interlayer insulation layer overlays the gate (step S204); and, a metal plug is formed in the interlayer insulation layer (step S205).

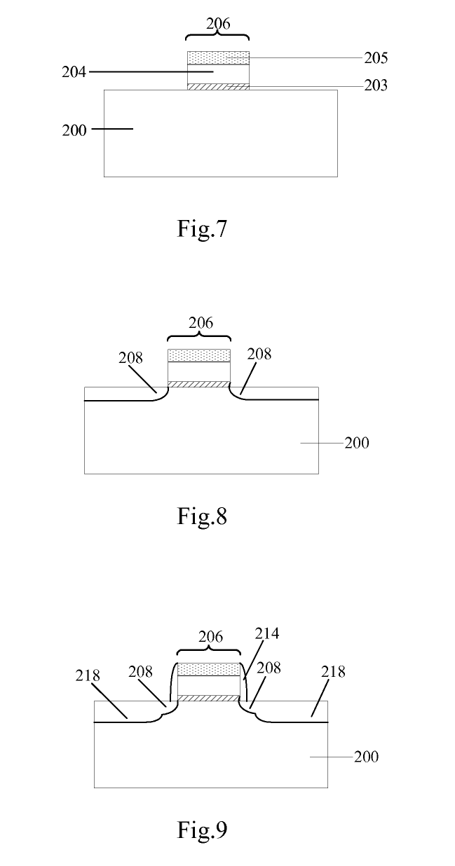

FIGS. 7 to 12 are cross-sectional views illustrating a method for manufacturing a semiconductor device according to the present invention. As shown in FIG. 7, a gate dielectric layer 203 made of silicon oxide is formed over a semiconductor substrate 200 by thermal oxidation method. A polysilicon layer 204 is formed on the gate dielectric layer 203 by chemical vapor deposition. Then, an antireflection layer 205 made of silicon nitride is formed on the polysilicon layer 204 by chemical vapor deposition for protecting said polysilicon layer during the subsequent etching. A first photoresist layer (not shown) is formed on the antireflection layer 205, which defines a subsequent gate pattern by exposure and development. The antireflection layer 205, the polysilicon layer 204 and the gate dielectric layer 203 are etched sequentially along the gate pattern by using the first photoresist layer as a mask until the semiconductor substrate 200 is exposed, and then a gate 206 is formed.

As shown in FIG. 8, the first photoresist layer is removed by ashing method. Using the gate 206 as a mask, ions are planted into the semiconductor substrate 200 at each side of the gate 206 to form a slightly doped drain 208.

In this embodiment, if the device is a PMOS, p-type ions such as Boron ions are planted into the semiconductor substrate 200 to form the slightly doped drain 208. If the device is a NMOS, n-type ions such as Phosphorus ions are planted into the semiconductor substrate 200 to form the slightly doped drain 208.

As shown in FIG. 9, spacers 214 is formed on both sides of the gate 206 by high density plasma chemical vapor deposition, which together with the gate 206 forms a gate structure. Using the gate structure as a mask, ions are planted into the semiconductor substrate 200 to form a source/drain 218.

In this embodiment, if the device is a PMOS, p-type ions such as Boron ions are planted into the semiconductor substrate 200 to form the source/drain 218. If the device is a NMOS, n-type ions such as Phosphorus ions are planted into the semiconductor substrate 200 to form the source/drain 218.

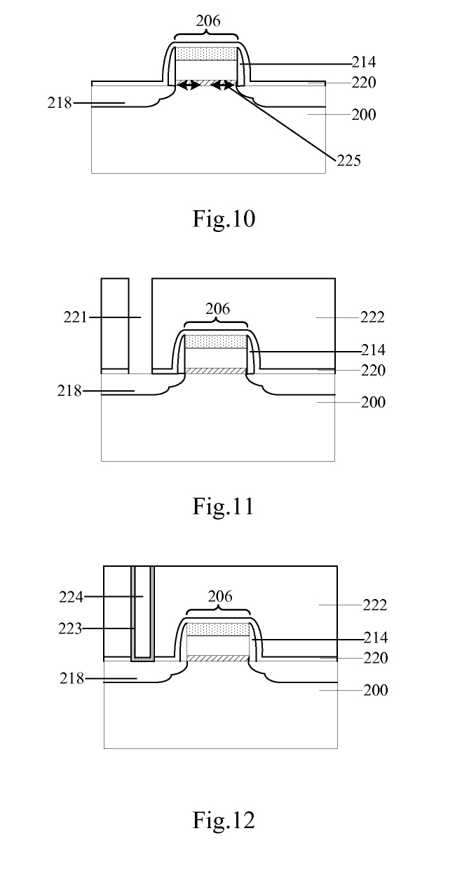

As shown in FIG. 10, an etching barrier layer 220 having a thickness in a range of 300 angstroms to 500 angstroms is formed on the gate 206, spacers 214 and the source/drain 218 by chemical vapor deposition for protecting the structure beneath said etching barrier layer 220 during the subsequent etching. The etching barrier layer 220 is made of silicon nitroxide or a combination of silicon nitroxide with silicon nitride. The defects of the interface between the gate dielectric layer 203 and the semiconductor substrate 200 are presented due to the effect of stress from the deposited etching barrier layer 220. Then, the thus-obtained structure is put into a heating oven; in the meantime hydrogen is supplied into the heating oven to carry out annealing. As a result, the dangling bond 225 between silicon oxide in the gate dielectric layer 203 and silicon adjacent to the interface of semiconductor substrate 200 is ended and the interface energy level is lowered.

In this embodiment, the hydrogen annealing is carried out at a temperature in a range of 400° C. to 500° C., such as 400° C., 420° C., 440° C., 460° C., 480° C. or 500° C.

The hydrogen annealing is carried out during a period in a range of 20 minutes to 30 minutes, such as 20 minutes, 22 minutes, 24 minutes, 26 minutes, 28 minutes or 30 minutes. In this embodiment, the etching barrier layer 220 has a thicknesses of, for example, 300 angstroms, 320 angstroms, 340 angstroms, 360 angstroms, 380 angstroms, 400 angstroms, 420 angstroms, 440 angstroms, 460 angstroms, 480 angstroms or 500 angstrom.

As shown in FIG. 11, an interlayer insulation layer 222 made of silicon oxide having a thickness of 8000 angstroms to 12000 angstroms is deposited on the etching barrier layer 220 by chemical vapor deposition for isolation between devices. A second photoresist layer (not shown) is formed on the interlayer insulation layer 222. A pattern for defining a subsequent contact hole is formed by exposure and development. Using the second photoresist layer as a mask, the interlayer insulation layer 222 and the etching barrier layer 220 on the gate 206 are etched along the pattern of the contact hole until the antireflection layer 205 is exposed. As an alternative, the interlayer insulation layer 222 and the etching barrier layer 220 on the source/drain 218 are etched along the pattern of the contact hole until the semiconductor substrate 200 is exposed. Thus a contact hole 221 is formed.

In this embodiment, for example, the interlayer insulation layer 222 has a thicknesses of 8000 angstroms, 8500 angstroms, 9000 angstroms, 9500 angstroms, 10000 angstroms, 10500 angstroms, 11000 angstroms, 11500 angstroms or 12000 angstrom.

As shown in FIG. 12, the second photoresist layer is removed by ashing method. A diffusion barrier layer 223 is deposited on the interlayer insulation layer 222 and the inner surfaces of the contact hole by high density plasma chemical vapor deposition to prevent the subsequently deposited metal from diffusing into the interlayer insulation layer 222. The diffusion barrier layer 223 is made of titanium or titanium nitride or a combination of titanium with titanium nitride. A metal tungsten layer is formed on the diffusion barrier layer 223 by chemical vapor deposition, and the contact hole is completely filled with the metal tungsten. The diffusion barrier layer 223 and the metal tungsten layer are polished by Chemical Mechanical Polish (CMP) until the interlayer insulation layer 222 is exposed. And then a tungsten plug 224 is formed.

While the present invention has been described with respect to certain preferred embodiments, it will be apparent to those skilled in the art that various changes and modifications may be made without departing from the spirit and scope of the invention as defined in the following claims.

What is claimed is:

1. A method for manufacturing a semiconductor device, which comprises the steps of:
providing a semiconductor substrate comprising a gate, a source and a drain, wherein the gate comprises a gate dielectric layer disposed on the semiconductor substrate;
forming an etching barrier layer on the semiconductor substrate; and
subjecting the resulted structure to hydrogen annealing.

2. The method as claimed in claim 1, wherein said hydrogen annealing is carried out at a temperature in a range of 400° C. to 500° C.

3. The method as claimed in claim 2, wherein said hydrogen annealing is carried out during a period in a range of 20 minutes to 30 minutes.

4. The method as claimed in claim 1, wherein said etching barrier layer is made of silicon nitroxide.

5. The method as claimed in claim 4, wherein said etching barrier layer has a thickness in a range of 300 angstroms to 500 angstroms.

6. A method for manufacturing a semiconductor device, which comprises the steps of:
providing a semiconductor substrate comprising a gate, a source and a drain, wherein the gate comprises a gate dielectric layer disposed on the semiconductor substrate;
forming an etching barrier layer on the semiconductor substrate;
subjecting the resulted structure to hydrogen annealing;
forming an interlayer insulation layer on the etching barrier layer, wherein the interlayer insulation layer overlays the gate; and
forming a metal plug in the interlayer insulation layer.

7. The method as claimed in claim 6, wherein said hydrogen annealing is carried out at a temperature in a range of 400° C. to 500° C.

8. The method as claimed in claim 7, wherein said hydrogen annealing is carried out during a period in a range of 20 minutes to 30 minutes.
